(19) United States
(12) Patent Application Publication
(10) Pub. No.: US 2012/0034707 A1
(43) Pub. Date: Feb. 9, 2012

(54) ATOMICALLY PRECISE NANORIBBONS AND RELATED METHODS

(76) Inventors: Sujit S. Datta, Cambridge, MA (US); Douglas R. Strachan, Lexington, KY (US); Samuel M. Khamis, San Francisco, CA (US); Alan T. Johnson, JR., Philadelphia, PA (US); Yaping Dan, Cambridge, MA (US)

(21) Appl. No.: 12/995,562

(22) PCT Filed: Jun. 1, 2009
(86) PCT No.: PCT/US09/45824

§ 371 Date: Mar. 9, 2011

Related U.S. Application Data
(60) Provisional application No. 61/057,917, filed on Jun. 2, 2008.

(51) Int. Cl. G01N 27/00; B32B 9/04; B32B 5/00; B32B 3/30; B32B 5/16; B32B 7/04; H01L 31/02; C01B 31/02; B05D 1/12; B32B 3/00; B82Y 15/00

(52) U.S. Cl. 436/501; 216/83; 427/180; 428/688; 428/220; 428/156; 428/143; 428/148; 428/58; 136/252; 423/448; 423/445 R; 422/82.01; 977/773; 977/734

(57) ABSTRACT

Disclosed are atomically precise nanoribbons formed by gradient-driven catalytic etching of crystalline substrates to produce edges formed along specific crystallographic axes by thermally-activated particles. Also provided are related methods for fabrication of these nanoribbon structures. Further provided are devices and related methods for power generation and for detection of specific targets using the disclosed structures.

### CROSS-REFERENCE TO RELATED APPLICATIONS

This application claims the benefit of priority to U.S. Ser. No. 61/057,917, filed Jun. 2, 2008, the contents of which are incorporated herein in their entirety.

### STATEMENT OF GOVERNMENT INTEREST

The government may have certain rights in this invention. At least a portion of the work underlying the claimed invention was supported by National Science Foundation grant NSEC DMR-0425780, JSTO DTRA Army Research Office Grant #W911NF-06-1-0462, and the Intelligence Community Postdoctoral Fellowship Program, National Geospatial Agency Grant No. HM1582-07-1-2014.

### TECHNICAL FIELD

The present invention is directed toward the fields of nanoparticles and of catalytic etching of crystalline surfaces.

### BACKGROUND

Due to their remarkable electronic properties, few layer graphene (“FLG”) and other layered materials are attractive candidates for use in post-silicon nanoelectronic devices incorporating quantum size effects. Of particular interest is the construction of atomically precise graphene nanoribbons, in which charge carriers are confined in the lateral dimension whereby the electronic properties are controlled by the width and specific crystallographic orientation of the ribbon; such structures hold enormous promise as nanoscale devices, and hold the additional advantage that graphene's and other layered materials' two-dimensionality lend themselves to existing device architectures based on planar geometries.

To date, however, such structures have so far been impossible to achieve due to the rough, non-crystalline edges that result from existing, state-of-the-art nanolithography techniques. It is believed that these rough edges are a limiting factor to attaining useful performance and on-off current ratios from nano-scale graphene devices.

Accordingly, there is a need in the art for nanoscale structures and devices having crystalline edges. There is also a parallel need for methods of fabricating such structures and devices.

### SUMMARY

In meeting the described challenges, the claimed invention first provides methods for etching crystalline materials, comprising providing a material comprising one or more crystallographic axes, one or more catalytic particles being disposed on the material; applying a gradient so as to displace one or more catalytic particles, and the applying being performed under such conditions that the one or more catalytic particles reacts with the material so as to remove at least a portion of the material.

Also provided are methods of forming workpieces, comprising disposing a quantity of a catalyst on a crystalline structure having at least one edge; heating the catalyst so as to give rise to the formation of one or more catalyst particles, the heating giving rise to the migration of one or more catalyst particles.

Further disclosed are crystalline articles, comprising crystalline structures comprising at least one edge, essentially the entire length of the at least one edge being defined by two or more crystallographic axes of the crystalline material.

Provided are workpieces, comprising crystalline structures comprising carbon, the crystalline structure comprising at least one edge, and at least one catalyst particle disposed proximate to the at least one edge.

The present invention also provides electronic devices, comprising crystalline articles comprising at least first and second regions, the first and second regions being bounded by at least two edges, the at least two edges each defined by two or more neighboring crystallographic axes of the carbonaceous crystalline material, the first and second regions each being characterized as being essentially straight, the first and second regions meeting at a juncture, and the juncture giving rise to a voltage drop between the first and second regions.

Additionally disclosed are methods of generating power, comprising providing a crystalline article comprising at least first and second regions, the first and second regions being bounded by at least two edges, the at least two edges each defined by two or more neighboring crystallographic axes of the carbonaceous crystalline material, the first and second regions each being characterized as being essentially straight, the first and second regions meeting at a juncture, the juncture effecting a voltage drop between the first and second regions; and directing one or more photons against the crystalline article within a distance from the juncture approximately equal to mean free path of an electron so as to generate an electrical current.

Further disclosed are detector devices, comprising: a crystalline structure comprising at least two edges, the at least two edges each defined by two or more crystallographic axes of the crystalline material, and the crystalline structure comprising at least one detector moiety complementary to a specific target, the at least one detector moiety in electrical communication with the crystalline body; and at least one electrical conductor in electrical communication with the crystalline body.

Also provided are methods for detecting a target, comprising providing a crystalline article comprising at least first and second regions, the first and second regions being bounded by at least two edges, the at least two edges each defined by two or more crystallographic axes of the crystalline material; the crystalline article comprising at least one detector moiety complementary to a specific target; exposing the crystalline article to a sample; and monitoring the crystalline article for interactions between the at least one detector moiety and the specific target.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. In the drawings:

FIG. 1. depicts single-particle crystallographic etching of few-layer graphene: (A) AFM and SEM images of trenches etched in FLG samples supported on a SiO₂/Si substrate, scale bars are 250 nm (top left), 800 nm (top right), and 250 nm (bottom right), and the width of inset image is 315 nm, and the color scale of AFM images is 15 nm; (B) Histogram showing total etched trench length versus trench angle, chosen so the main peak is at 0° (FLG edge is at ˜34°), open circles show the data average over seven adjacent points; red curve is a five-peak Gaussian fit, and the inset shows histogram data (open circles) as a polar plot; and (C) a schematic of one embodiment of the disclosed processes;

FIG. 2 depicts a method for the mass-production of nano-scale graphene devices according to the claimed invention: (a) a graphene sheet (dark blue body with circles disposed thereon) is connected by two large metallic pads made of a material (such as molybdenum) capable of withstanding a 900° C. etching temperature, and metallic particles (yellow circles) are nano-lithographically defined on the graphene; (b) the metallic particles are migrated at high temperature in one specific direction by an applied electric current between the large metallic electrodes; and (c) the resulting narrow graphene strips that can be utilized for constructing devices;

FIG. 3 depicts a proposed method for the mass-production of nano-scale graphene devices utilizing an applied magnetic field: (a) a graphene sheet (dark blue body) with metallic particles (yellow circles) nano-lithographically defined next to the graphene; (b) the metallic particles are migrated at high temperature in one specific direction by an applied magnetic field gradient, and (c) resultant narrow graphene strips that can be utilized for constructing devices;

FIG. 4 depicts silver (Ag) nanoparticle formation along the edges of few-layer graphene sheets imaged under SEM;

FIG. 5 depicts a close-up view of nanoparticles disposed proximate to the edges of few-layer graphene sheets;

FIG. 6 depicts initial experiments with Fe nanoparticles alignment along graphene edges, and there was an observed tendency for the Fe particles to align along step edges of the few-lay graphene (at the top of the figure);

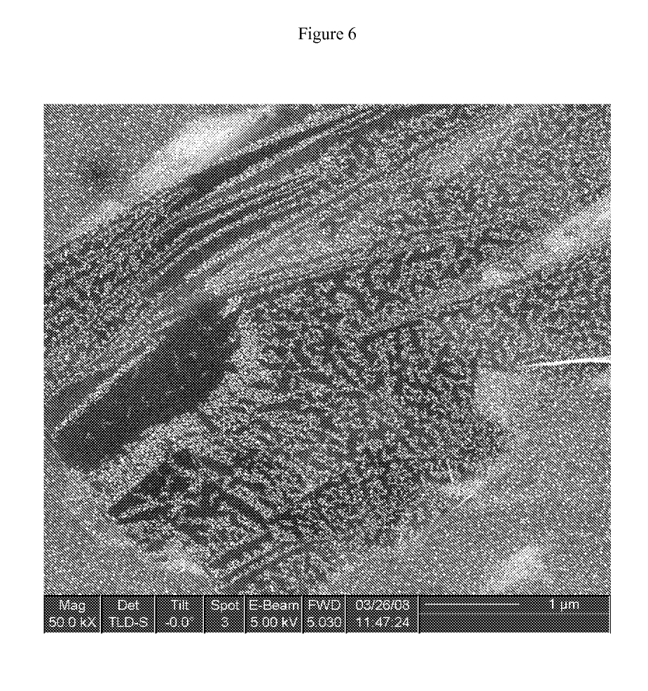

FIG. 7 depicts a proposed method for the mass-aligned nano-particle etching of graphene. (a) initial graphene sheet, (b) deposition of a thin (<1 nm) layer of metal, (c, d) initial low-temperature (˜500° C.) annealing to form the nanoparticles and allow them to migrate to the edges where they become immobilized (due to their lower mobility along the edges);

FIG. 8 depicts the proposed application of graphene nanoribbon arrays towards diodes and photovoltaic cells and detectors, (a) a reported diode device formed from a carbon nanotube with a random kink (occurring with an approximate probability of 1 in 500 nanotubes; the cartoon of the kinked nanotube is taken from Z. Yao, et al., Nature 402, 273 (1999)); and (b) mass aligned nanoribbon arrays;

FIG. 9 depicts single-particle crystallographic etching of few-layer graphene, (A) SEM image of nanotrenches etched in FLG (dark) supported on SiO₂/Si substrate (light); scale bar is 800 nm. Small circles are Fe nanoparticles, inset image, width 315 nm, shows an AFM image (color scale 15 nm) of a graphene nanoribbon defined using parallel etched trenches, of measured width ˜35 nm, (B) AFM image (color scale 15 nm) of etched FLG sample, showing straight nanotrenches etched down to the substrate defining a triangle of side length ˜650 nm; scale bar is 250 nm, (C) a 3-dimensionals AFM surface plot of an etched FLG sample, showing parallel, straight nanotrenches;

FIG. 10 depicts (A) AFM image of etched FLG with parallel nanotrenches etched by catalyst nanoparticles; scale bar is 250 nm, color scale is 25 nm, (B) height profile along the line in left image, showing nanotrench etched down to the underlying SiO₂/Si substrate of width ˜20 nm, due to the finite size of the AFM tip, measured nanotrench heights (for trenches of width less than about 20 nm) appear shorter; and

FIG. 11 depicts a schematic view of an iron particle being manipulated by a gradient, during which manipulation the iron particle catalyzes the removal of the carbon—graphene—substrate along crystallographic axes; and

FIG. 12 depicts a schematic view of (left-hand image) a hexagonal crystal unit and (right-hand image) a schematic view of trenches etched in a crystalline substrate, as shown in A. K. Geim and A. H. MacDonald, Physics Today, p. 35 (August 2007).

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

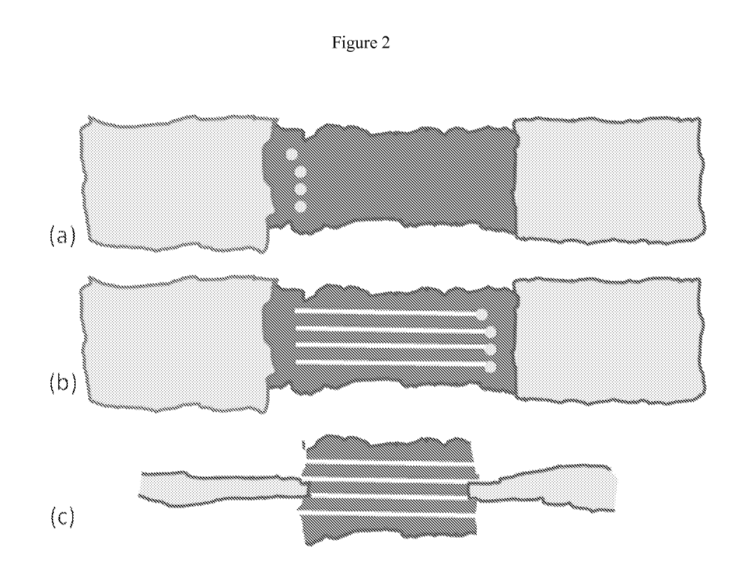

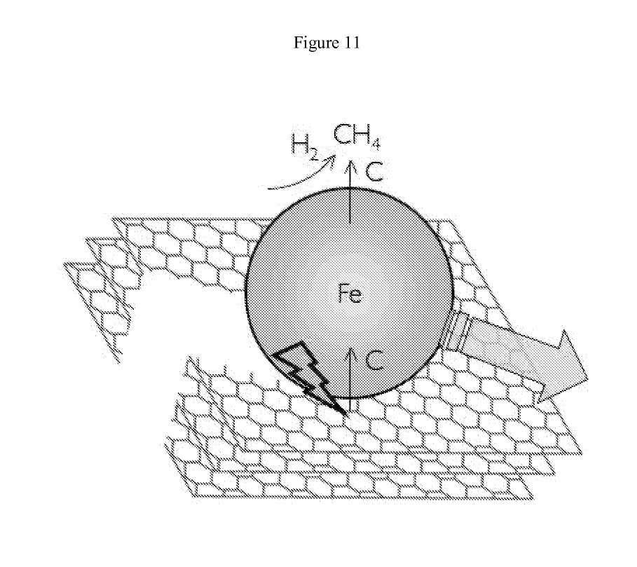

The present invention first provides methods for etching crystalline materials. The claimed methods include providing a material comprising one or more crystallographic axes, one or more catalytic particles being disposed on the material; and applying a gradient so as to displace one or more catalytic particles, the applying being performed under such conditions that the one or more catalytic particles reacts with the material so as to remove at least a portion of the material, as shown, e.g., in FIGS. 2, 3, 7, and 11.

The crystalline material to be etched suitably includes carbon. Graphene is considered especially suitable, although other materials composed at least partially of crystalline sheets or layers are considered suitable. Such materials include boron, boron nitride, titanium oxide, tungsten sulfide, molybdenum sulfide, and the like; other suitable materials will be apparent to those of ordinary skill in the art. Conducting and semiconducting materials are suitable.

The methods are suitably applied to materials that are less than about 10 nm in thickness, or even less than about 5 nm or even 3 nm in thickness. In some embodiments, the methods are applied to materials that are about 1 nm in thickness.

Catalytic particles used in the claimed methods suitably include metals, alloys, nanocrystals, inorganic nanocrystals, nanodots, nanotubes, and the like. Transition metals, Al, Ga, In, Tl, Si, Ge, Sn, Pb, Po, and the like are all considered suitable for the particles in the claimed methods.

In some embodiments, the catalytic particles include one or more nanoparticles having a characteristic cross-sectional dimension in the range of from about 1 nm to about 100 nm, or from about 10 nm to about 50 nm. The optimal size of the catalytic particles used in a given application will depend on the needs and constraints of the user.

The particles are suitably disposed on a surface of the at least one layer of material. For example, the particles may be disposed on the top surface of the uppermost layer in a stack or other assembly of grapheme layers. One or more catalytic particles is suitably proximate to one or more edges of the layer of material. In some embodiments, this means that one or more particles are disposed on the upper surface of the material next to the an edge of the material. In other embodiments, this means that one or more particles are disposed around the rim of the edge of the substrate.

The methods suitably include application of one or more gradients to one or more particles so as to displace, motivate, or manipulate the one or more particles. Gradients may be electrical or magnetic fields, and can also be electric currents or gaseous flows. The choice of gradient will be dictated by the user's needs and constraints, and may be dependent on the materials used in a given application.

Gradients may be applied in one or multiple directions. The gradients may also be constant or varying, as is dictated by the user's needs.

In the claimed methods, the reaction of the one or more catalytic particles with the at least one material suitably removes at least a portion of the material. This removal may be accomplished by a gasification reaction. In other embodiments, the removal is accomplished by some other type of reaction that removes substrate material proximate to the particle. Application of the gradient is suitably performed under such conditions, such as heating, that one or more particles reacts with substrate material so as to remove or displace substrate material.

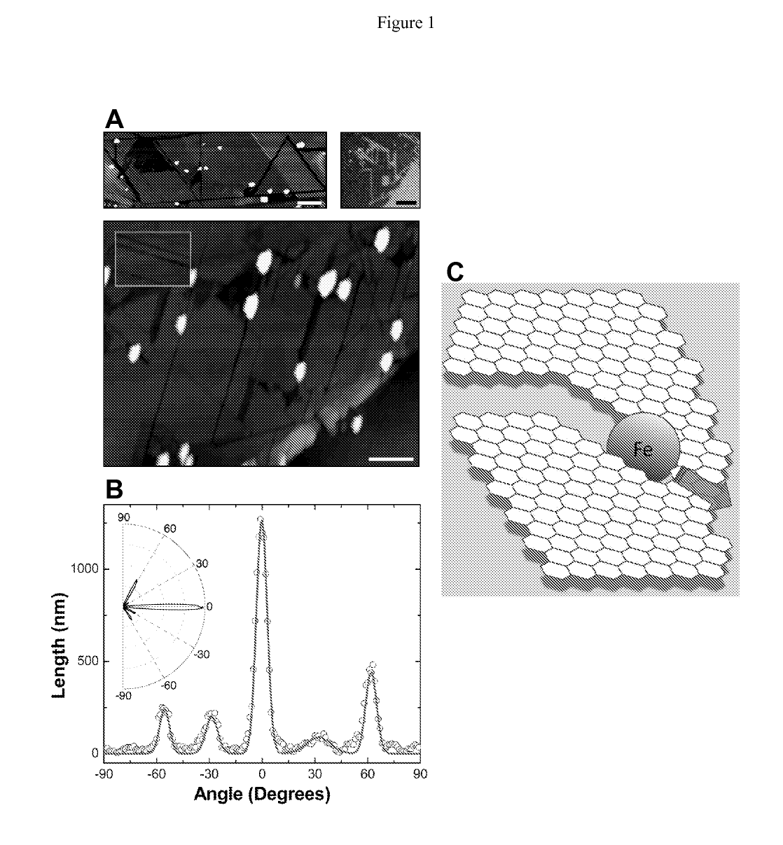

Without being bound to any one theory of operation, it is believed that the etching procedure likely occurs by a hydrogenation mechanism. In one embodiment wherein iron nanoparticles etch graphene substrate material, a methane-forming reaction is, it is believed, catalyzed by the catalytic nanoparticles (e.g., FIG. 1C), beginning at active carbon atoms at FLG edges and following a continuous crystallographic track. It is believed—without being tied to any single theory of operation—that this is due to favorable adhesion and wetting of the graphite surface along these specific directions, and it is observed, as described elsewhere herein that etched trenches commence from the edges of the FLG sheets (e.g., FIG. 1A).

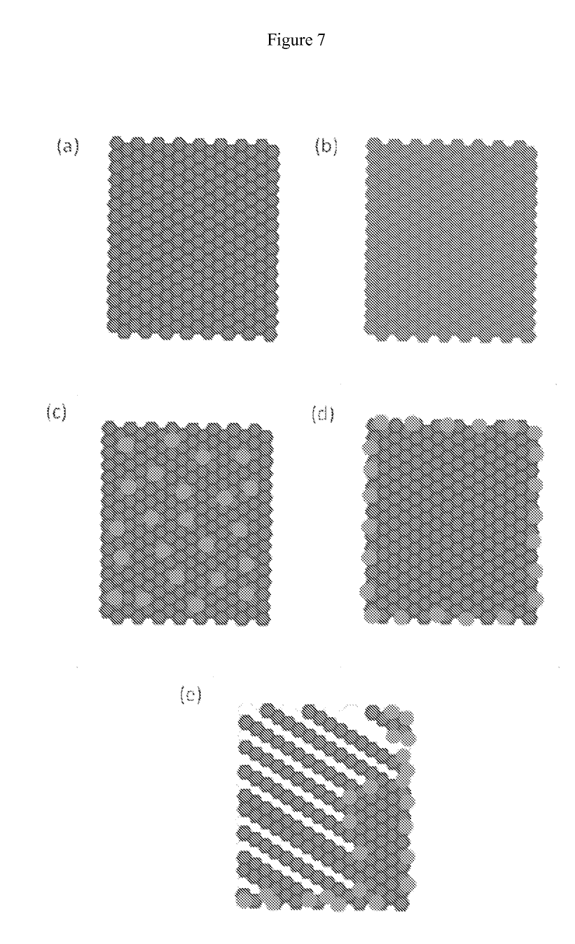

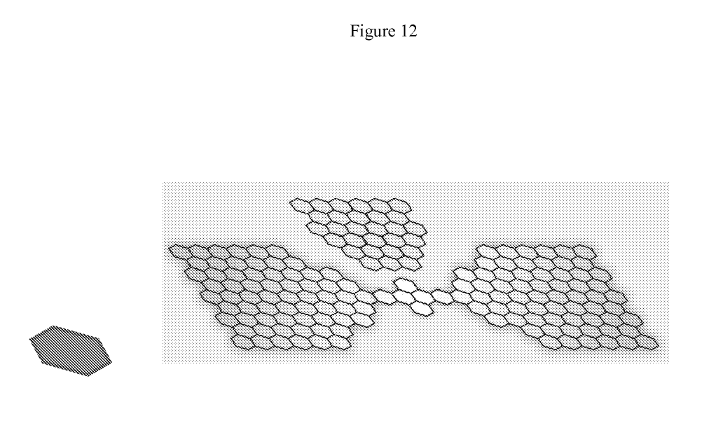

Application of the gradient also suitably displaces or motivates one or more particles along one or more crystallographic axes of the material. For purposes of the present application, “crystallographic axis” means an edge that is periodic—on an atomic scale—with the crystal lattice of the substrate. FIG. 1(c), for example, shows an edge that is periodic with the crystal lattice of a substrate. Such edges are also shown in FIG. 7e and FIG. 12.

In some embodiments, the substrate material is disposed on an insulator. The claimed invention also include materials, structures, and devices that are etched according to the claimed methods.

Also provided are methods of forming workpieces, which workpieces may be used in other articles of manufacture. These methods include disposing a quantity of a catalyst on a crystalline structure having at least one edge, heating the catalyst so as to give rise to the formation of one or more catalyst particles, and where application of heat gives rise to the migration of one or more catalyst particles. Exemplary, non-limiting workpieces are shown in FIGS. 7d and 7e.

Suitable crystalline materials are described elsewhere herein. Structures may be layers, planes, rods, plateaus, wafers, and the like. The structures are suitably less than about 10 nm in thickness at least one location, and can be less than about 5 nm or can even about 1 nm in thickness.

Suitable catalyst materials that are disposed on the crystalline structure include, for example, metal oxides. Other materials that give rise to particles upon heating are also considered suitable; materials that include one or more metals are considered especially suitable.

Disposition of the quantity of catalyst is suitably accomplished by evaporation, chemical vapor deposition, physical vapor deposition, coating, spraying, and the like. The catalyst is suitably disposed as a layer, but may also be disposed as more discrete regions.

The heating is suitably modulated so as to essentially avoid promoting etching reactions between the catalyst particles and the crystalline substrate. In such embodiments, the heating—and other environmental conditions—are modulated so as to promote formation of catalytic particles and are also suitably modulated to promote the migration of one or more catalytic particles to one or more edges of the crystalline structure. The heating and other environmental conditions can be modulated so as to give rise to one or more catalyst particles being disposed proximate to at least one edge of the crystalline structure.

Workpieces made according to the claimed methods are also within the scope of the claimed invention.

Further provided are crystalline articles. Such articles suitably include crystalline structures having at least one edge, where essentially the entire length of the at least one edge is defined by two or more crystallographic axes of the crystalline material. Suitably, at least a portion of the crystalline structure being is disposed on an insulating substrate.

Suitable substrates are described elsewhere herein, and include, for example, grapheme and other crystalline, layered materials. The structures may be less than about 10 nm in thickness, or less than 5 nm in thickness. In some embodiments, the structures are about 1 nm in thickness.

In some embodiments, the article includes two or more edges that define a middle region, or void, therebetween. Such voids are suitably trench-like in cross section, but may also, in some embodiments, be channel-like, conduit-like, or have other recessed or grooved conformations.

At least a portion of the width of such a void or middle region is suitably less than about 100 nm. The width can be less than 50 nm, 10 nm, or even 1 nm.

The length of an edge of the claimed articles may be between about 1 nm up to about 10,000 nm. Edges may also have a length of between about 10 nm to about 1000 nm, or even from about 50 nm to about 500 nm.

It is considered particularly suitable for the articles of the present invention to, as described elsewhere herein, include one or more channels. Such channels are suitably defined by at least two walls that are themselves defined by one or more crystallographic edges of the crystalline structure. The bottoms of such channels are, in some embodiments, defined by the substrate atop which the crystalline structure is disposed. The top of such channels is suitably even with or about even with the upper surface of the crystalline structure, e.g., FIG. 1c. Channels may be about 100 nm wide or less than 100 nm in width. Channels are suitably 10 nm or less in depth, which depth may be dictated by the thickness of the substrate in which the channels are formed.

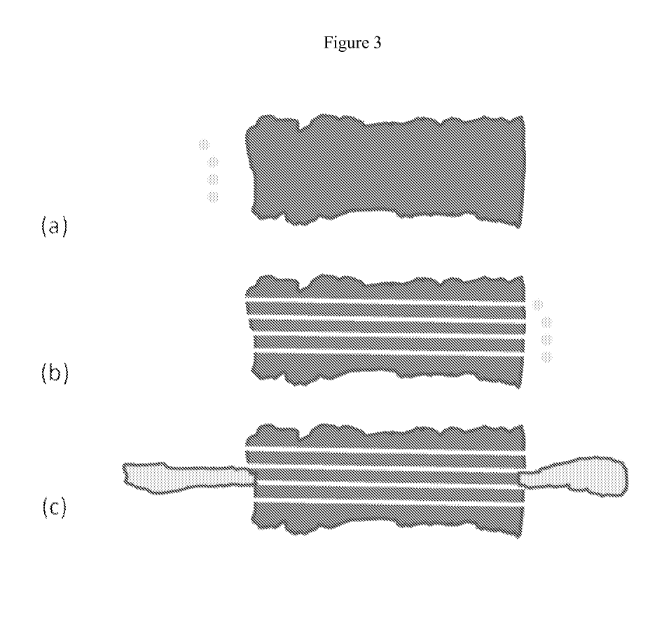

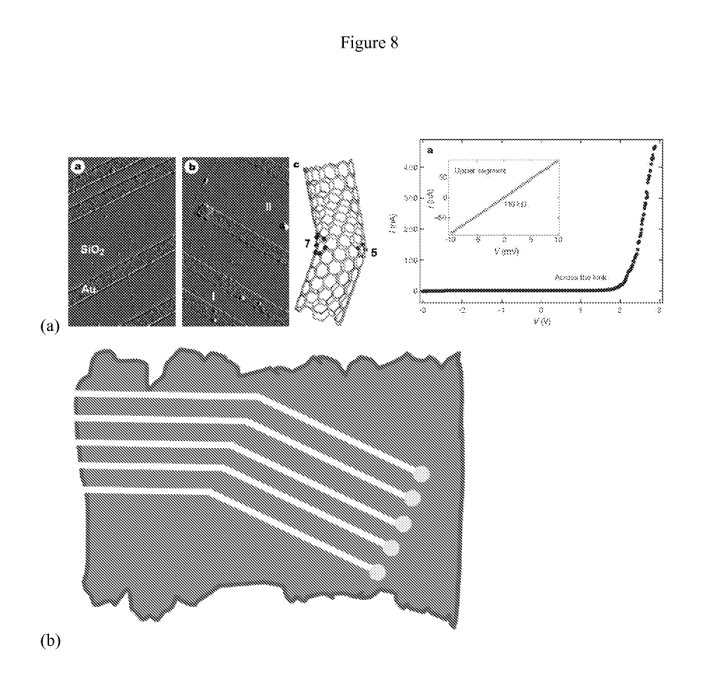

The claimed articles also include crystalline regions that are bounded by two or more channels. Such regions may be described as ribbons, strips, and the like. Such regions are shown in, e.g., FIG. 2, FIG. 3, FIG. 7, and FIG. 8. In some configurations, multiple channels may be used to define a mesa- or pillar-like region of substrate material. The optimal configuration of channels will be dictated by the needs of the user.

In some embodiments, shown in FIG. 2 and FIG. 3, the articles include one or more electrical connections. These connections may be used to supply or collect power or current as dictated by the user's needs.

Also provided are workpieces, the workpieces including crystalline structures that include carbon. The structures suitably include one or more edges, with one or more catalyst particles disposed proximate to the edge or edges. As described elsewhere herein, the particles may be disposed on the supper surface of the structure, next to an edge, or the particles may be disposed on a side-wall of the structure, next to an edge. Dimensions of suitable structures are described elsewhere herein, as are suitable catalyst particles. Workpieces are shown, e.g., in FIGS. 7d and 7e.

Also provided are electronic devices. These devices suitably include a crystalline article comprising at least first and second regions, which regions are bounded by at least two edges and are, for example, strip-like or ribbon-like in form. As described elsewhere herein, such edges are suitably defined by two or more periodic crystallographic axes of the carbonaceous crystalline material.

The first and second regions are suitably characterized as being essentially straight and meet at a juncture, which juncture is suitably kinked or bent, such as that shown in FIG. 8b. In some embodiments, the first and second regions are perpendicular to one another. In other embodiments, the first and second regions join at acute or obtuse angles.

The juncture suitably gives rise to a voltage drop between the first and second regions. Without being bound to any particular theory of operation, it is believed that angled junctions between regions of certain materials give rise to a voltage drop at or around the location of the junction.

Suitable crystalline articles, such as wafers and the like, are described elsewhere herein, as are suitable materials. In some embodiments, at least a portion of the crystalline structure is disposed atop an insulating substrate.

The first region, the second region, or both, is suitably described as having a characteristic dimension—such as, for example, width—of less than about 100 nm, or less than about 50 nm, or even less than about 10 nm.

In some embodiments, the devices are constructed so as to allow photons directed incident to the device to contact the crystalline structure within a distance about equal to the mean free path of an electron from the juncture. Without being bound to any single theory of operation, it is believed that such devices are capable of generating power by virtue of the current evolved by the impact of the photons with the crystalline structure.

The disclosed devices are suitably used as transistors, diodes, photovoltaic devices, and the like. Other applications for such devices will be apparent to those of ordinary skill in the art.

Also provided are methods for power generation. These methods include providing a crystalline article having at least first and second regions that are each bounded by at least two edges defined by two or more neighboring crystallographic axes of the carbonaceous crystalline material, and the first and second regions each being characterized as being essentially straight. The first and second regions suitably meet at a juncture that effects a voltage drop between the first and second regions.

The methods also include directing one or more photons against the crystalline article within a distance from the juncture approximately equal to mean free path of an electron so as to generate an electrical current; suitable dimensions for the first and second regions are described elsewhere herein.

The claimed methods also include harvesting the power evolved by the current at the vicinity of the juncture. The harvesting is suitably accomplished by collecting the power evolved within the crystalline article, which collection may be accomplished by electrical connections. In some embodiments, the methods include collecting evolved power to a storage device, such as a battery or other capacitor.

Also provided are detector devices. These devices include crystalline structures or bodies having comprising at least two edges each defined by two or more crystallographic axes of the crystalline material. The structures also include one or more detector moieties that are complementary to one or more specific targets, which detector moieties are suitably in electrical communication with the crystalline body. The devices also suitably include one or more electrical conductors in electrical communication with the crystalline body.

Suitable crystalline structures are carbonaceous; suitable materials are described elsewhere herein and include, for example, graphene.

Detector moieties include proteins, polymers, nucleotides, monomers, ligands, receptors, and the like. The claimed devices may include one or more particular types of detector moieties, and devices capable of detecting more than one target are contemplated.

The devices also, in some embodiments, include one or more devices capable of detecting changes in the electrical characteristics of the crystalline structure. As one non-limiting example, a detector device may include a moiety capable of binding to a particular antibody, and when that antibody binds to the moiety and effects a change in the electrical characteristic of the crystalline structure to which the moiety is connected, that change is registered.

Also provided are related methods for detecting targets. These methods include providing a crystalline articles comprising detector moieties—as described elsewhere herein, exposing the crystalline article to a sample; and monitoring the crystalline article for interactions (such as binding or the release of binding) between the at least one detector moiety and the specific target.

In suitable embodiments, an interaction between the at least one detector moiety and the specific target effects one or more detectable changes in an electrical characteristic of the crystalline article. At least one of these changes is suitably detected to as to provide the user with information regarding the presence or lack of a particular target.

### EXAMPLES AND NON-LIMITING EMBODIMENTS

For some experiments, the initial samples (before etching) consisted of pristine few-layer graphene sheets transferred onto highly-doped Si substrates with 300 nm thermally-grown SiO₂ by mechanical exfoliation under ambient conditions. Flakes of few-layer graphene were identified using optical microscopy. Height imaging of the samples was done using a Veeco Dimension 3100 atomic force microscope (AFM) operating in intermittent contact mode, with Si₃N₄-coated tips (NSC15, Mikromasch) of curvature radius <20 nm. Samples were also characterized using a JEOL JSM6400 scanning electron microscope (with a LaB₆ filament).

The FLG on SiO₂/Si substrates were uniformly spin-coated with ˜15 mL solution of 50 mg/L Fe(NO₃)₃.9H₂O in isopropyl alcohol (HPLC grade). The samples were then transferred to a furnace and heated in hydrogen and argon gas co-flow (320 sccm/600 sccm, respectively) at 900° C. for 45 minutes. At these temperatures the Fe accumulated to form small ˜15 nm diameter nanoparticles which diffuses along the surface of SiO₂ and graphene. Without being bound to any particular theory, as the nanoparticles diffused over the surface of the SiO₂ and graphene at these elevated temperatures, the nanoparticles etched away the FLG sheets.

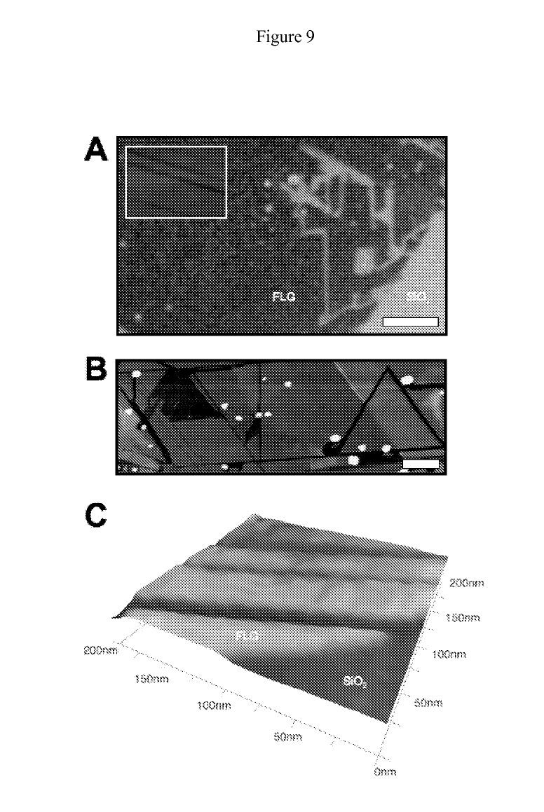

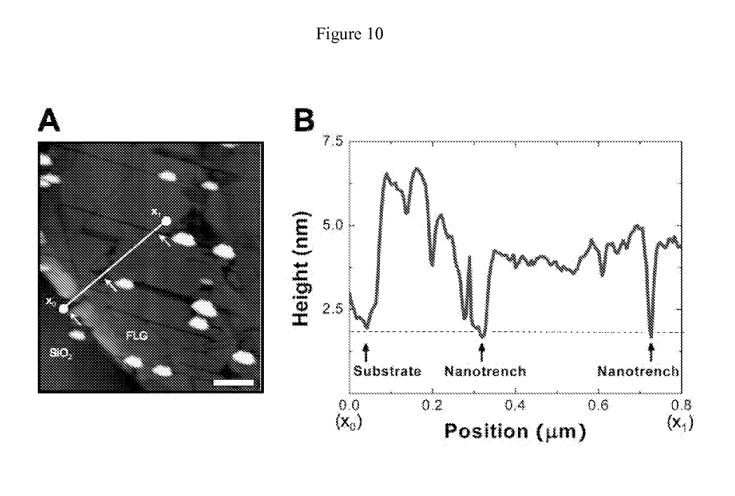

FIG. 9 shows AFM and SEM images of FLG samples after this etching procedure. Crucially, we observe relatively long and straight (>1 μm) nanotrenches in the FLG along which graphene has been completely removed. The majority of these trenches are etched completely down to the insulating substrate. This is evident through contrast variations in SEM images and through detailed AFM height analysis of the nanotrenches (FIG. 9). Cross-section analysis (as in FIG. 10) showed that the depths of the trenches corresponded to the difference in height between the bare substrate and the FLG flake. Without being bound to any single theory of operation, these data suggested that the trench forming process results in tracks that are etched completely down to the insulating substrate. AFM imaging also revealed that the widths of the trenches are on the order of tens of nanometers; frequently less than about 20 nm.

Measurements of the lengths and orientations of etched FLG trenches revealed striking correlations with the graphene lattice. FIG. 1 shows a histogram of total etched trench length versus angle for the FLG sample of FIG. 10A. Typically, particle tracks travel predominantly along a single direction with other preferred directions at ±60° relative to this. Other directions at 30 degree intervals were also observed. No significant correlation was found between the orientation of the etched nanotrenches and the direction of gas flow. The existence of these track directions spaced at 30° intervals supported the notion that the etched trenches are commensurate with the graphene honeycomb lattice—i.e., the single-particle etching procedure resulted in well-defined crystallographic edges. In addition to other structures, we have used this single-particle etching technique to fabricate graphene nanoribbons of widths measured using AFM as small as ˜15 nm and lengths on the order of microns (e.g., inset to FIG. 9).

FLG etching with metallic nanoparticles likely occurred by a hydrogenation mechanism. This reaction, catalyzed by the Fe nanoparticles, is given by

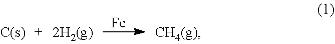

in which the graphene acts as the carbon source C(s). Further evidence that this reaction is the source of the crystallographic etching is found from experiments performed in hydrogen-free argon gas flow which do not result in nanotrench formation.

As the Fe particles diffuse on the SiO₂ surface, they reacted with active carbon atoms at the graphene edges. This appeared to initiate nanotrench formation, and the moving Fe nanoparticles removed carbon atoms in the graphene along tracks aligned with the underlying crystal lattice with high precision, forming the observed nanotrenches (FIG. 1C). The vast majority of etched trenches commenced from the edges of the FLG sheets, with an Fe nanoparticle at the end of each trench. Isolated nanoparticles were sometimes observed on top of FLG flakes without any etch track, suggesting (without being bound to any particular theory) that carbon atoms at FLG edges (as compared to those on the FLG surface) were reactive and more likely to initiate nanotrench formation.

The fact that the etching occurred as the nanoparticles moved over an amorphous SiO₂ surface indicated that the crystallographic orientation of the trenches are determined from the interfacial interactions of the nanoparticle with the edge of the FLG. This crystallographic etching could—without being bound to any particular theory—be due to the favorable adhesion and wetting of the Fe nanoparticles to the graphene edge along specific crystallographic directions. Another potential mechanism for the disclosed crystallographic etching technique is the crystallographic dependence of the Fe-graphene reactivity—for example, due to lowered activation energy of the reaction given in Eq. 1 along specific directions commensurate with the FLG lattice.

Crystallographic Etching of Graphene with Metallic Particles

To etch graphene along it crystallographic axes samples of mechanically-exfoliated FLG (supported on a Si wafer with 300 nm thermally-grown SiO₂) coated with a solution of 50 mg/L Fe(NO₃)₃.9H₂O in isopropyl alcohol were heated in a furnace to 900° C. under co-flowing hydrogen and argon gas (320 sccm/600 sccm, respectively) for 45 minutes. At these elevated temperatures the Fe forms nanoparticles which diffuse over the surface of the graphene and SiO₂.

As the particles move they reacted with and remove carbon atoms in the graphene along tracks that are aligned with the underlying crystal lattice to high precision. FIG. 1A shows atomic force microscope (AFM) and scanning electron microscope (SEM) images of FLG samples with these etch tracks. Crucially, the majority of the tracks were etched completely down to the insulating substrate. This was evident from differences in contrast variations through SEM images and through detailed AFM height analysis of the tracks. AFM imaging also revealed that the widths of the trenches are frequently less than 10 nm.

Measurements of the lengths and orientations of etched FLG trenches reveal striking correlations with the graphene lattice; FIG. 1B shows a histogram of total etched trench length versus angle for a representative FLG sample. Typically, particle tracks traveled predominantly along a single direction with other preferred directions at ±60° relative to this. Slightly less preferred directions at 30 degree intervals are also observed. The existence of these track directions spaced at 30° intervals gives strong support to the notion that the etched trenches are commensurate with the graphene honeycomb lattice—that is, our single-particle etching procedure results in well-defined crystallographic edges. In addition to other structures, we have used this single-particle etching technique to fabricate graphene nanoribbons of width on the order of tens of nanometers and lengths on the order of microns (e.g., inset to FIG. 1A).

Devices Fabricated with Crystallographically Etched Graphene

The above outlined crystallographic etching of graphene is suited for nano-scale device fabrication. This is due to the fact that the etching provides a method to slice graphene that is supported on an insulating substrate, allowing for the construction of specific crystallographically oriented nanoribbons. Developing a method to mass produce crystallographically oriented nanoribbons of graphene requires methods of controlling the motion of the metallic particles during the etching process. Below are proposed several methods to achieve controlled motion for the mass production of nano-scale devices from single graphene sheets.

To achieve this control we propose to utilize applied electric currents and applied magnetic fields during the etching cycle. A schematic of the proposed processing is shown in FIG. 2. First, a graphene sheet (FIG. 2(a)) is connected by two large metallic pads made of a material (such as molybdenum) that can withstand the 900° C. etching temperature. Metallic particles (yellow dots in FIG. 2(b)) are then nano-lithographically defined on the graphene. These metallic particles are migrated at high temperature in one specific direction by an applied electric current between the two large electrodes which results in narrow graphene strips. At this stage the leads can be selectively etched away (using, e.g., an appropriate wet etchant or other selective removal process), leaving behind nanoribbons that can be connected to nano-lithographically defined leads, resulting in working nanoscale devices (FIG. 2(c)).

An alternative method to controllably construct nanoribbons with crystallographic edges is to use externally applied magnetic field gradients to drive the ferromagnetic particles (FIG. 3). To achieve this, the magnetic particles may be utilized at a temperature below their Curie temperature (T_{C}), in order that the particles remain magnetic during the processing. This is achievable by, for example, Fe or Co nanoparticles. The use of a magnetic field eliminates the need for sacrificial electrodes. In addition, the metallic particles need not be placed onto the graphene surface. Instead, the particles can be placed to the side of the graphene, and they can then be driven into (and, in some embodiments, through) the graphene via interaction with the applied field.

Method for Aligning Metallic Nanoparticles Along the Graphene Edge

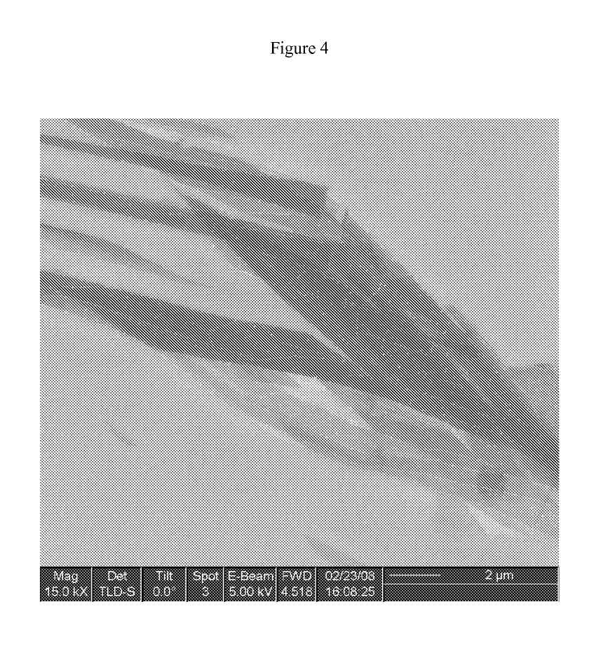

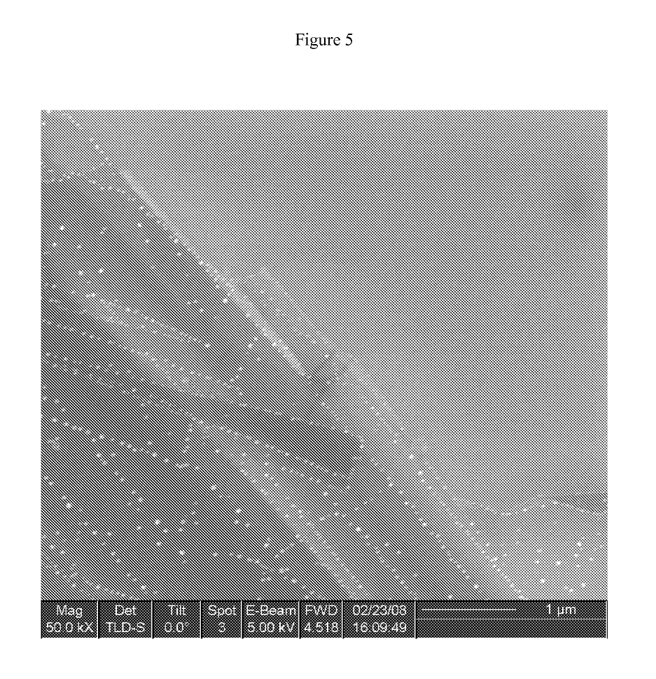

Also developed were methods for aligning metallic nanoparticles precisely along the edge of graphene which will allow for arrays of nanoribbons to be fabricated. FIG. 4 shows few-layer graphene sheets that have had a sub-nanometer layer of Ag evaporated onto its surface. A low-temperature 30 minute anneal allows the Ag to migrate on the surface of the graphene and form small nanoparticles along its edges (as seen in FIG. 4 and FIG. 5).

### SUMMARY

In conclusion, provided are methods by which few-layer graphene, among other materials, is etched along crystallographic directions down to the underlying substrate, which etching is useful in, e.g., development of electronics devices. This technique relies on the use of individual nanoparticles as catalysts to carve out trenches, grooves, or channels with crystallographic edges in layered samples. The disclosed methods and devices thus enable atomically precise construction of integrated transistors, circuits, chemical sensors, and spin valves from layered materials.

What is claimed:

1. A method for etching a crystalline material, comprising:
providing a material comprising one or more crystallographic axes,
one or more catalytic particles being disposed on the material;
applying a gradient so as to displace one or more catalytic particles,
the applying being performed under such conditions that the one or more catalytic particles reacts with the material so as to remove at least a portion of the material.

2. The method of claim 1, wherein the material comprises carbon.

3. The method of claim 1, wherein the material comprises graphene, boron, boron nitride, titanium oxide, tungsten sulfide, molybdenum sulfide, or any combination thereof.

4. The method of claim 1, wherein the material is less than about 10 nm in thickness.

5. The method of claim 4, wherein the material is less than about 5 nm in thickness.

6. The method of claim 1, wherein the one or more catalytic particles comprise a metal, an alloy, an inorganic nanocrystal or any combination thereof.

7. The method of claim 1, wherein the metal comprises a transition metal, Al, Ga, In, Tl, Si, Ge, Sn, Pb, Po, or any combination thereof.

8. The method of claim 1, wherein the one or more catalytic particles comprises one or more nanoparticles having a characteristic cross-sectional dimension in the range of from about 1 nm to about 100 nm.

9. The method of claim 8, wherein the one or more catalytic particles comprises one or more nanoparticles having a characteristic cross-sectional dimension in the range of from about 10 nm to about 50 nm.

10. The method of claim 1, wherein the one or more catalytic particles comprise nanoparticles, nanocrystals, nanodots, nanotubes, or any combination thereof.

11. The method of claim 1, wherein the one or more catalytic particles are disposed on a surface of the at least one layer of material.

12. The method of claim 1, wherein the one or more catalytic particles are proximate to one or more edges of the layer of material.

13. The method of claim 1, wherein the gradient comprises an electric field, a magnetic field, an electric current flow, a gaseous flow, or any combination thereof.

14. The method of claim 1, wherein the gradient is applied in a single direction.

15. The method of claim 1, wherein the gradient is applied in two or more directions.

16. The method of claim 1, wherein the reaction of the one or more catalytic particles with the at least one material removes at least a portion of the material.

17. The method of claim 1, wherein the reaction of the one or more catalytic particles with the at least one material gasifies at least a portion of the material.

18. The method of claim 1, wherein the one or more catalytic particles are displaced along one or more crystallographic axes of the material.

19. The method of claim 1, wherein the at least one layer of material is disposed on an insulator.

20. The etched material according to claim 1.

21. A method of forming a workpiece, comprising:
disposing a quantity of a catalyst on a crystalline structure having at least one edge;
heating the catalyst so as to give rise to the formation of one or more catalyst particles,
the heating giving rise to the migration of one or more catalyst particles.

22. The method of claim 21, wherein the catalyst comprises at least one metal.

23. The method of claim 21, wherein the disposing a quantity of catalyst is accomplished by evaporation, chemical vapor deposition, physical vapor deposition, coating, spraying, or any combination thereof.

24. The method of claim 21, wherein the quantity of catalyst is characterized as a layer.

25. The method of claim 24, wherein the structure comprises an average thickness of less than about 10 nm.

26. The method of claim 24, wherein the structure comprises an average thickness of less than about 5 nm.

27. The method of claim 26, wherein the structure comprises an average thickness of less than about 1 nm.

28. The method of claim 21, wherein the heat is modulated so as to essentially avoid promoting etching reactions between the catalyst particles and the crystalline substrate.

29. The method of claim 21, wherein the heating is modulated so as to promote etching reactions between the catalyst particles and the crystalline structure.

30. The method of claim 21, wherein the heating gives rise to one or more catalyst particles being disposed proximate to at least one edge of the crystalline structure.

31. The method of claim 21, wherein the heating gives rise to one or more particles migrating toward one or more edges of the crystalline structure.

32. The method of claim 21, wherein the heating gives rise to one or more particles being disposed proximate to one or more edges of the crystalline structure.

33. The workpiece made according to claim 21.

34. A crystalline article, comprising:
a crystalline structure comprising at least one edge,
essentially the entire length of the at least one edge being defined by two or more crystallographic axes of the crystalline material.

35. The crystalline article of claim 34, wherein at least a portion of the crystalline structure is disposed on an insulating substrate.

36. The crystalline article of claim 34, wherein the crystalline structure comprises carbon.

37. The crystalline article of claim 34, wherein the crystalline structure comprises graphene.

38. The crystalline article of claim 34, wherein the material is less than about 10 nm in thickness.

39. The crystalline article of claim 34, wherein the material is less than about 5 nm in thickness.

40. The crystalline article of claim 34, comprising two or more edges defining a middle region therebetween.

41. The crystalline article of claim 40, wherein at least a portion of the middle region comprises a width of less than about 100 nm.

42. The crystalline article of claim 40, wherein at least a portion of the middle region comprises a width of less than about 10 nm.

43. The crystalline article of claim 40, wherein at least a portion of the middle region comprises a width of less than about 5 nm.

44. The crystalline article of claim 41, wherein at least a portion of the middle region comprises a width of less than about 50 nm.

45. The crystalline article of claim 44, wherein at least a portion of the middle region comprises a width of less than about 10 nm.

46. The crystalline article of claim 34, wherein the edge comprises a length of from about 1 nm to about 10,000 nm.

47. The crystalline article of claim 34, wherein the edge comprises a length of from about 10 nm to about 1000 nm.

48. The crystalline article of claim 34, wherein the edge comprises a length of from about 50 nm to about 500 nm.

49. The crystalline article of claim 34, wherein the crystalline structure comprises one or more channels,
each of the one or more channels having a bottom and being defined by at least two walls, and
each of the two walls being defined by one or more crystallographic axes of the crystalline structure.

50. The crystalline article of claim 49, wherein the top of at least one channel is essentially even with the upper surface of the crystalline structure.

51. The crystalline article of claim 49, wherein a channel comprises a width of less than about 100 nm.

52. The crystalline article of claim 49, wherein the channel is less than about 10 nm deep.

53. The crystalline article of claim 52, wherein the channel is less than about 5 nm deep.

54. The crystalline article of claim 49, wherein at least a portion of the bottom of one or more channels is defined by the insulating substrate.

55. The crystalline article of claim 54, further comprising a region bounded by two or more channels.

56. A workpiece, comprising:
a crystalline structure comprising carbon,
the crystalline structure comprising at least one edge;
at least one catalyst particle disposed proximate to the at least one edge.

57. The workpiece of claim 56, wherein the crystalline structure comprises a thickness of less than about 10 nm.

58. The workpiece of claim 56, wherein the crystalline structure comprises a thickness of less than about 5 nm.

59. The workpiece of claim 56, wherein the crystalline structure comprises graphene, boron, boron nitride, titanium oxide, tungsten sulfide, molybdenum sulfide, or any combination thereof.

60. The workpiece of claim 56, wherein the one or more catalytic particles comprise a metal, an alloy, an inorganic nanocrystal, or any combination thereof.

61. The workpiece of claim 56, wherein the metal comprises a transition metal, Al, Ga, In, Tl, Si, Ge, Sn, Pb, Po, or any combination thereof.

62. The workpiece of claim 56, wherein the one or more catalytic particles comprises a nanoparticle having a characteristic cross-sectional dimension in the range of from about 1 nm to about 100 nm.

63. The workpiece of claim 56, wherein the one or more catalytic particles comprises a nanoparticle having a characteristic cross-sectional dimension in the range of from about 10 nm to about 50 nm.

64. The workpiece of claim 56, wherein the one or more catalytic particles comprise nanoparticles, nanocrystals, nanodots, nanotubes, or any combination thereof.

65. An electronic device, comprising:
a crystalline article comprising at least first and second regions,
the first and second regions being bounded by at least two edges,
the at least two edges each defined by two or more neighboring crystallographic axes of the carbonaceous crystalline material,
the first and second regions each being characterized as being essentially straight,
the first and second regions meeting at a juncture,
the juncture giving rise to a voltage drop between the first and second regions.

66. The electronic device of claim 65, wherein the crystalline article comprises carbon.

67. The electronic device of claim 66, wherein the crystalline article comprises graphene.

68. The electronic device of claim 65, wherein the first region, the second region, or both, comprise a characteristic dimension of less than about 100 nm.

69. The electronic device of claim 65, wherein the first region, the second region, or both, comprise a characteristic dimension of less than about 50 nm.

70. The electronic device of claim 65, wherein the first region, the second region, or both, comprise a characteristic dimension of less than about 10 nm.

71. The electronic device of claim 65, wherein the juncture is characterized as being kinked or bent.

72. The electronic device of claim 65, wherein the device is adapted so as to allow photons directed incident to the device to contact the crystalline structure within a distance about equal to the mean free path of an electron from the juncture.

73. The electronic device of claim 65, wherein the electronic device is used as a transistor, a diode, a photovoltaic device, or any combination thereof.

74. The electronic device of claim 65, wherein at least a portion of the electronic device is disposed on an insulating substrate.

75. A method for generating power, comprising:
providing a crystalline article comprising at least first and second regions,
the first and second regions being bounded by at least two edges,
the at least two edges each defined by two or more neighboring crystallographic axes of the carbonaceous crystalline material,
the first and second regions each being characterized as being essentially straight,
the first and second regions meeting at a juncture,
the juncture effecting a voltage drop between the first and second regions;
directing one or more photons against the crystalline article within a distance from the juncture approximately equal to mean free path of an electron so as to generate an electrical current.

76. The method of claim 75, wherein the first region, the second region, or both, comprise a characteristic dimension of less than about 100 nm.

77. The method of claim 75, wherein the first region, the second region, or both, comprise a characteristic dimension of less than about 50 nm.

78. The method of claim 75, wherein the first region, the second region, or both, comprise a characteristic dimension of less than about 10 nm.

79. The method of claim 75, wherein the juncture is characterized as being kinked or bent.

80. The method of claim 75, further comprising harvesting the power evolved by the current at the vicinity of the juncture.

81. A detector device, comprising:
a crystalline structure comprising at least two edges,
the at least two edges each defined by two or more crystallographic axes of the crystalline material, and
the crystalline structure comprising at least one detector moiety complementary to a specific target,
the at least one detector moiety in electrical communication with the crystalline body; and
at least one electrical conductor in electrical communication with the crystalline body.

82. The detector device of claim 81, wherein the crystalline structure comprises a carbonaceous material.

83. The detector device of claim 81, wherein the carbonaceous material comprises graphene.

84. The detector device of claim 81, wherein the detector moiety comprises a protein, a polymer, a nucleotide, a monomer, a ligand, a receptor, or any combination thereof.

85. The detector device of claim 81, further comprising a device capable of detecting changes in the electrical characteristics of the crystalline structure.

86. A method for detecting a target, comprising:
providing a crystalline article comprising at least first and second regions,
the first and second regions being bounded by at least two edges,
the at least two edges each defined by two or more crystallographic axes of the crystalline material;
the crystalline article comprising at least one detector moiety complementary to a specific target;
exposing the crystalline article to a sample; and
monitoring the crystalline article for interactions between the at least one detector moiety and the specific target.

87. The method of claim 86, wherein the article comprises a characteristic dimension of less than about 100 nm.

88. The method of claim 87, wherein the article comprises a characteristic dimension of less than about 50 nm.

89. The method of claim 88, wherein the article comprises a characteristic dimension of less than about 10 nm.

90. The method of claim 86, wherein an interaction between the at least one detector moiety and the specific target effects one or more detectable changes in an electrical characteristic of the crystalline article.
